(19) United States
(12) Patent Application Publication
(10) Pub. No.: US 2023/0268203 A1
(43) Pub. Date: Aug. 24, 2023

(54) HEATING UNIT AND SUBSTRATE TREATING APPARATUS INCLUDING THE SAME

(71) Applicant: SEMES CO., LTD., Chungcheongnam-do (KR)

(72) Inventors: Jin Taek Oh, Chungcheongnam-do (KR); Jong Seok Seo, Chungcheongnam-do (KR); Seung Han Lee, Chungcheongnam-do (KR); Dongwoon Park, Seoul (KR)

(21) Appl. No.: 18/111,537

(22) Filed: Feb. 18, 2023

(30) Foreign Application Priority Data
Feb. 21, 2022 (KR) 10-2022-0022285

(51) Int. Cl. H01L 21/67; H05B 3/28; F27B 17/00; G03F 7/20

(52) U.S. Cl. CPC H01L 21/67103; H05B 3/28; F27B 17/0025; G03F 7/70875

(57) ABSTRACT

Provided are a heating unit including an air layer for thermal insulation and a substrate treating apparatus including the heating unit. The substrate treating apparatus includes: a housing providing a space in which a substrate is treated; a heating unit disposed in the housing and heating the substrate; a cooling unit disposed in the housing and cooling the substrate; and a transfer unit for moving the substrate, wherein the heating unit includes: a body including a heater therein; a first air layer provided inside the body for thermal insulation and formed in a first direction as a longitudinal direction thereof; and a second air layer provided inside the body for thermal insulation and formed in a second direction as a longitudinal direction thereof.

This application claims the benefit of Korean Patent Application No. 10-2022-0022285, filed on Feb. 21, 2022, in the Korean Intellectual Property Office, the disclosure of which is incorporated herein in its entirety by reference.

### BACKGROUND

### 1. Field

The present disclosure relates to a heating unit and a substrate treating apparatus including the same, and more particularly, to a heating unit applicable to a process of manufacturing a semiconductor and a substrate treating apparatus including the heating unit.

### 2. Description of the Related Art

A semiconductor manufacturing process may be continuously performed in a semiconductor manufacturing facility and may be divided into a pre-process and a post-process. The semiconductor manufacturing facility may be installed in a space defined as a fab to manufacture semiconductors.

The pre-process refers to a process of forming a circuit pattern on a wafer to complete a chip. The pre-process may include a deposition process for forming a thin film on a wafer, a photolithography process for transferring a photoresist onto the thin film using a photomask, an etching process for selectively removing unnecessary parts using a chemical substance or a reactive gas to form a desired circuit pattern on the wafer, an ashing process for removing the photoresist remaining after the etching, an ion implantation process for implanting ions into a part connected to the circuit pattern to give characteristics of an electronic device, and a cleaning process for removing contaminants from the wafer.

The post-process refers to a process of evaluating the performance of a product completed through the pre-process. The post-process may include a primary inspection process for sorting out good and bad products by inspecting the operation of each chip on a wafer, a package process for cutting and separating each chip through dicing, die bonding, wire bonding, molding and marking to form a product shape, and a final inspection process for finally inspecting the characteristics and reliability of a product through an electrical characteristics test and a burn-in test.

In the photolithography process, a bake chamber may be used to heat-treat a substrate (e.g., a wafer). However, when the substrate is heat-treated using the bake chamber, a large amount of heat is lost through upper and side surfaces of the bake chamber. Accordingly, the internal temperature of the bake chamber becomes non-uniform, and substrate treatment performance is degraded.

### SUMMARY

Aspects of the present disclosure provide a heating unit including an air layer for thermal insulation and a substrate treating apparatus including the heating unit.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided a substrate treating apparatus including: a housing providing a space in which a substrate is treated; a heating unit disposed in the housing and heating the substrate; a cooling unit disposed in the housing and cooling the substrate; and a transfer unit for moving the substrate, wherein the heating unit includes: a body including a heater therein; a first air layer provided inside the body for thermal insulation and formed in a first direction as a longitudinal direction thereof; and a second air layer provided inside the body for thermal insulation and formed in a second direction as a longitudinal direction thereof.

According to another aspect of the present disclosure, there is provided a substrate treating apparatus including: a housing providing a space in which a substrate is treated; a heating unit disposed in the housing and heating the substrate; a cooling unit disposed in the housing and cooling the substrate; and a transfer unit for moving the substrate, wherein the heating unit includes: a body including a heater therein and having a space for air purge and exhaust; a first air layer provided inside the body for thermal insulation and formed in a first direction as a longitudinal direction thereof; and a second air layer provided inside the body for thermal insulation and formed in a second direction as a longitudinal direction thereof, wherein the space for air purge and exhaust includes a first space, a second space connected to the first space and disposed above the first space, a third space connected to the second space and disposed above the second space and a fourth space connected to the third space and disposed on sides of the third space, the first air layer is provided above the third space and the fourth space, and the second air layer is provided at the same level as the fourth space but is separated from the fourth space.

According to another aspect of the present disclosure, there is provided a heating unit for heat-treating a substrate. The heating unit includes: a heating plate including a body providing a surface on which the substrate is mounted and a heater installed inside the body; a cover covering a top of the heating plate when the substrate is heat-treated; and an actuator for moving the cover, wherein the heating plate includes: a first air layer provided inside the body for thermal insulation and formed in a first direction as a longitudinal direction thereof; and a second air layer provided inside the body for thermal insulation and formed in a second direction as a longitudinal direction thereof.

### BRIEF DESCRIPTION OF THE DRAWINGS

These and/or other aspects will become apparent and more readily appreciated from the following description of the embodiments, taken in conjunction with the accompanying drawings in which:

FIG. 1 is a plan view schematically illustrating the structure of a substrate treating apparatus according to an embodiment of the present disclosure;

FIG. 2 is a cross-sectional view schematically illustrating the structure of the substrate treating apparatus according to the embodiment of the present disclosure;

FIG. 3 schematically illustrates the internal structure of a heating plate constituting the substrate treating apparatus according to the embodiment of the present disclosure;

FIG. 4 is an exemplary view illustrating the placement structure of a first air layer constituting the heating plate of FIG. 3;

FIG. 5 is an exemplary view for explaining a method of forming the first air layer constituting the heating plate of FIG. 3;

FIG. 6 is an exemplary view for explaining various embodiments of the first air layer constituting the heating plate of FIG. 3;

FIG. 7 is a first exemplary view illustrating the placement structure of a second air layer constituting the heating plate of FIG. 3;

FIG. 8 is a second exemplary view illustrating the placement structure of the second air layer constituting the heating plate of FIG. 3;

FIG. 9 is a third exemplary view illustrating the placement structure of the second air layer constituting the heating plate of FIG. 3; and

FIG. 10 is an exemplary view for explaining a method of forming the second air layer constituting the heating plate of FIG. 3.

### DETAILED DESCRIPTION

Hereinafter, embodiments of the present disclosure will be described in detail with reference to the accompanying drawings. Like reference numerals in the drawings denote like elements, and thus their description will be omitted.

The present disclosure relates to a heating unit including an air layer therein to improve thermal insulation performance and a substrate treating apparatus including the heating unit. The present disclosure will be described in detail below with reference to the drawings.

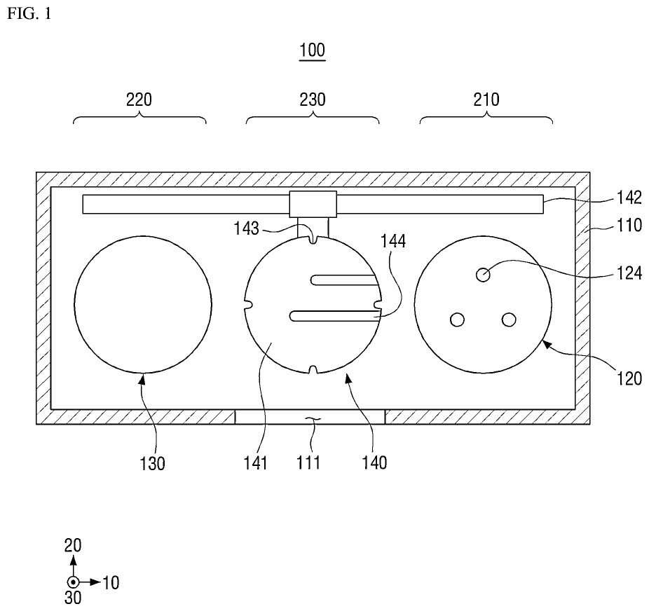

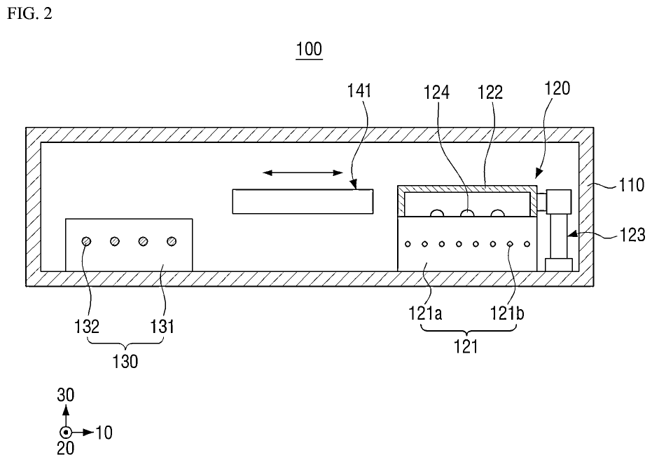

FIG. 1 is a plan view schematically illustrating the structure of a substrate treating apparatus 100 according to an embodiment of the present disclosure. FIG. 2 is a cross-sectional view schematically illustrating the structure of the substrate treating apparatus 100 according to the embodiment of the present disclosure.

Referring to FIGS. 1 and 2, the substrate treating apparatus 100 may include a housing 110, a heating unit 120, a cooling unit 130, and a transfer unit 140.

The substrate treating apparatus 100 is an apparatus for heating and cooling a substrate (e.g., glass or a wafer). The substrate treating apparatus 100 may heat and cool the substrate when a photolithography process is performed on the substrate. The substrate treating apparatus 100 may be provided as, for example, a bake chamber for performing a bake process.

The photolithography process may include a photoresist coating process, an exposure process, a development process, and a bake process. In this case, the substrate treating apparatus 100 may heat and/or cool the substrate before or after performing the coating process, that is, before or after coating a photoresist on the substrate.

However, the current embodiment is not limited thereto. The substrate treating apparatus 100 may also heat and/or cool the substrate before or after performing the exposure process. Alternatively, the substrate treating apparatus 100 may heat and/or cool the substrate before or after performing the development process.

The housing 110 provides a space for treating a substrate. The housing 110 may be installed to include the heating unit 120, the cooling unit 130, and the transfer unit 140 therein so that a substrate can be heated and cooled in the housing 110.

An opening 111 through which a substrate is inserted into or removed from the housing 110 may be formed in a sidewall of the housing 110. At least one opening 111 may be provided in the housing 110. The opening 111 may always be kept open. Alternatively, although not illustrated in FIG. 1, a door for opening or closing the opening may be provided.

The space inside the housing 110 may be divided into a heating region 210, a cooling region 220, and a buffer region 230. Here, the heating region 210 refers to a region where the heating unit 120 is disposed, and the cooling region 220 refers to a region where the cooling unit 130 is disposed. The heating region 210 may have the same width as the heating unit 120 but may also have a greater width than the heating unit 120. Similarly, the cooling region 220 may have the same width as the cooling unit 130 but may also have a greater width than the cooling unit 130.

The buffer region 230 refers to a region where a transfer plate 141 of the transfer unit 140 is disposed. The buffer region 230 may be provided between the heating region 210 and the cooling region 220. When the buffer region 230 is provided like this, the heating unit 120 and the cooling unit 130 may be spaced apart from each other by a sufficient distance. Thus, the heating unit 120 and the cooling unit 130 may be prevented from thermally interfering with each other. Like the heating region 210 and the cooling region 220, the buffer region 230 may have the same width as the transfer plate 141 or may have a greater width than the transfer plate 141.

When the heating unit 120, the cooling unit 130, and the transfer unit 140 are respectively disposed in the heating region 210, the cooling region 220, and the buffer region 230 inside the housing 110, they may be arranged in the order of the cooling unit 130, the transfer unit 140, and the heating unit 120 in a first direction 10. However, the current embodiment is not limited thereto. In the current embodiment, the heating unit 120, the cooling unit 130, and the transfer unit 140 may also be arranged in the order of the heating unit 120, the transfer unit 140, and the cooling unit 130 in the first direction 10.

The heating unit 120 is designed to heat a substrate. The heating unit 120 may provide a gas onto a substrate when heating the substrate. The heating unit 120 may provide, for example, a hexamethyldisilane gas. By providing such a gas, the heating unit 120 may improve an adhesion rate of photoresist to a substrate.

The heating unit 120 may be configured to include a heating plate 121 (or a hot plate), a cover 122, and an actuator 123 to heat a substrate.

The heating plate 121 applies heat to a substrate. To this end, the heating plate 121 may be configured to include a body 121a and heaters 121b.

The body 121a supports a substrate when heat is applied to the substrate. The body 121a may be formed to have the same diameter as the substrate or may be formed to have a greater diameter than the substrate.

The body 121a may be made of a metal having excellent heat resistance.

Alternatively, the body 121a may be made of a metal having excellent fire resistance. The body 121a may be made of, for example, ceramic such as aluminum oxide (Al₂O₃) or aluminum nitride (AlN).

Although not illustrated in FIGS. 1 and 2, the body 121a may include a plurality of vacuum holes that pass through the body 121a in an up-down direction (a third direction 30). Here, the vacuum holes may form vacuum pressure to fix a substrate in position when heat is applied to the substrate.

Although not illustrated in FIGS. 1 and 2, the body 121a may be divided into an upper plate and a lower plate disposed under the upper plate. In this case, a substrate may be mounted on the upper plate, and the heaters 121b may be installed inside the lower plate.

The heaters 121b are designed to apply heat to a substrate positioned on the body 121a. A plurality of heaters 121b may be installed inside the body 121a. The heaters 121b may be provided as heating resistors (e.g., hot wires) to which a current is applied. However, in the current embodiment, the heaters 150 may also be provided in any form other than the heating resistors as long as they can effectively apply heat to a substrate on the body 121a.

The cover 122 is formed to cover the top of the heating plate 121 when the heating plate 121 heats a substrate. The cover 122 may move upward or downward (the third direction 30) under the control of the actuator 123 to open or close the top of the heating plate 121.

The actuator 123 is designed to move the cover 122 upward or downward (the third direction 30). When a substrate to be heat-treated is mounted on the top of the heating plate 121, the actuator 123 may move the cover 122 down the housing 110 so that the cover 122 can completely cover the top of the heating plate 121. In addition, when heat treatment on the substrate is finished, the actuator 123 may move the cover 122 up the housing 110 to expose the top of the heating plate 121 so that the transfer unit 140 can transfer the substrate to the cooling unit 130.

The cooling unit 130 is designed to cool a substrate heated by the heating unit 120. To this end, the cooling unit 130 may be configured to include a cooling plate 131 and cooling members 132.

When high-temperature heat is applied to a substrate through the heating unit 120, the substrate may warp. The cooling unit 130 may cool the substrate heated by the heating unit 120 to an appropriate temperature so as to restore the substrate to its original state.

The cooling members 132 may be formed inside the cooling plate 131. The cooling members 132 may be provided in the form of passages through which a cooling fluid flows.

The transfer unit 140 is designed to move a substrate to the heating unit 120 or the cooling unit 130. To this end, the transfer unit 140 may have a hand, to which the transfer plate 141 is coupled, at an end thereof. The transfer unit 140 may move the transfer plate 141 along a guide rail 142 in a direction in which the heating unit 120 is located or in a direction in which the cooling unit 130 is located.

The transfer plate 141 may be disc-shaped and may be formed to have a diameter corresponding to that of a substrate. The transfer plate 141 may include a plurality of notches 143 formed along its rim, and a plurality of slit-shaped guide grooves 144 may be formed in an upper surface of the transfer plate 141.

The guide grooves 144 may extend from the rim of the transfer plate 141 toward a center the transfer plate 141. Here, the guide grooves 144 may be spaced apart from each other in the same direction (the first direction 10). When a substrate is transferred between the transfer plate 141 and the heating unit 120, the guide grooves 144 may prevent the transfer plate 141 and lift pins 124 from interfering with each other.

A substrate may be heated in a state where the substrate is placed directly on the heating plate 121 and may be cooled in a state where the transfer plate 141 on which the substrate is placed is in contact with the cooling plate 131. The transfer plate 141 may be made of a material (e.g., metal) having excellent heat transfer efficiency in order to facilitate heat transfer between the cooling plate 131 and the substrate.

Although not illustrated in FIGS. 1 and 2, the transfer unit 140 may receive a substrate from a substrate transfer robot installed outside the housing 110 through the opening 111 of the housing 110.

The lift pins 124 have a free-fall structure and serve to raise a substrate on the heating plate 121. When a bake process is to be performed on a substrate, the lift pins 124 may be lowered on the heating plate 121 after receiving the substrate from the transfer unit 140 in order to place the substrate on the heating plate 121. In addition, when the bake process on the substrate is finished, the lift pins 124 may be raised on the heating plate 121 to transfer the substrate to the transfer unit 140. To play this role, the lift pins 124 may be formed to penetrate the heating plate 121 in the up-down direction (the third direction 30).

Like the body 121a, the lift pins 124 may be made of a metal having excellent heat resistance or may be made of a metal having excellent fire resistance. In this case, the lift pins 124 may be made of the same metal as the body 121a, but they may also be made of different metals.

The lift pins 124 may be operated using, for example, a linear motor (LM) guide system and may be controlled by a plurality of cylinders connected to the LM guide system. The LM guide system has the advantage of being able to cope with high temperatures and high vibrations.

A plurality of lift pins 124 may be installed to stably support a substrate when the substrate is raised on the heating plate 121. As illustrated in FIGS. 1 and 2, three lift pins 124 may be installed.

As described above, when the heating unit 120 heats a substrate, it may lose heat in an upward direction (the third direction 30) and a lateral direction (the first direction 10 and a second direction 20). Accordingly, the temperature inside the heating unit 120 may become non-uniform, resulting in degradation of substrate treatment performance. In addition, it may take a lot of time to raise the surface temperature of the body to an appropriate temperature due to the loss of heat, and the amount of heat required to increase the temperature may also increase.

In order to solve these problems, in the current embodiment, the heating unit 120 may include an air layer therein to improve thermal insulation performance. This will now be described.

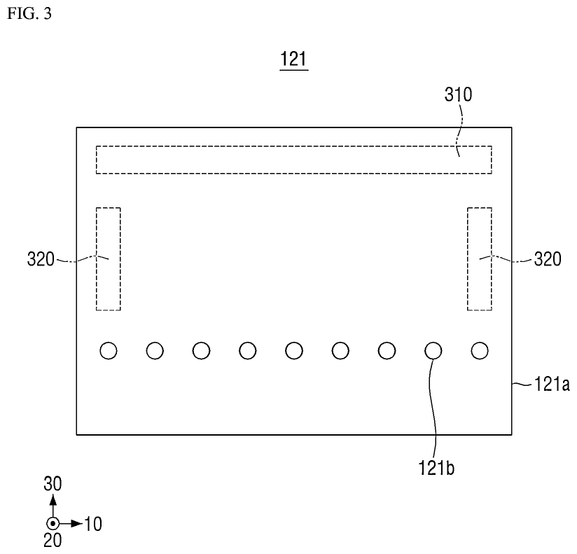

FIG. 3 schematically illustrates the internal structure of the heating plate 121 constituting the substrate treating apparatus 100 according to the embodiment of the present disclosure. Referring to FIG. 3, the heating plate 121 may be configured to include the body 121a, the heaters 121b, a first air layer 310, and a second air layer 320.

Since the body 121a and the heaters 121b have been described above with reference to FIGS. 1 and 2, a detailed description thereof will be omitted here.

The first air layer 310 may be formed by filling an empty space with air. The first air layer 310 may be formed in an upper portion inside the body 121a. Specifically, the first air layer 310 may be formed adjacent to an upper surface of the body 121a in the body 121a. When the heating plate 121 includes the first air layer 310 therein, the temperature uniformity of a substrate may be improved during a bake process of the substrate due to the thermal insulation effect of the first air layer 310.

The body 121a may have a space for air purge and exhaust flow. The first air layer 310 may be formed inside the body 121a without changing the internal space of the body 121a.

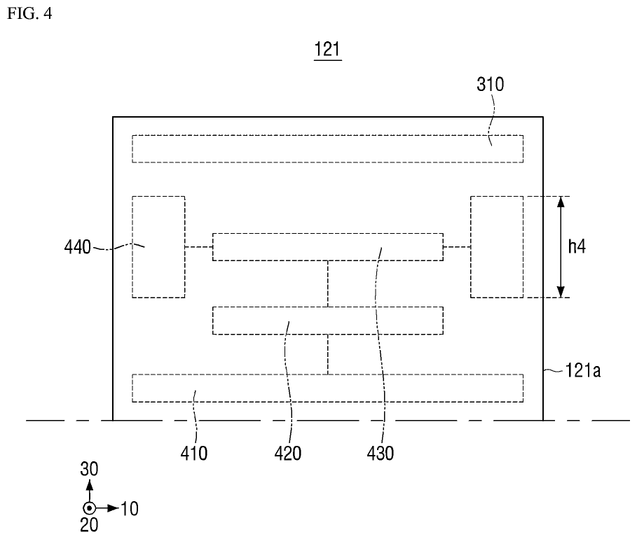

Referring to FIG. 4, the body 121a may include four spaces 410, 420, 430 and 440 such as a first space 410, a second space 420, a third space 430, and a fourth space 440. Here, the second space 420 may be connected to the first space 410 and disposed above the first space 410. In addition, the third space 430 may be connected to the second space 420 and disposed above the second space 420. In addition, the fourth space 440 may be connected to the third space 430 and disposed on sides of the third space 430.

When the body 121a includes the four spaces 410, 420, 430 and 440 as described above, it may be formed in a structure in which air purge is supplied to the first space 410 through the second space 420 and the third space 430 and exhausted through the fourth space 440. When the inside of the body 121a is formed in this structure, the first air layer 310 may be formed above the first through fourth spaces 410 through 440 and may be formed adjacent to the surface of the body 121a. FIG. 4 is an exemplary view illustrating the placement structure of the first air layer 310 constituting the heating plate 121 of FIG. 3.

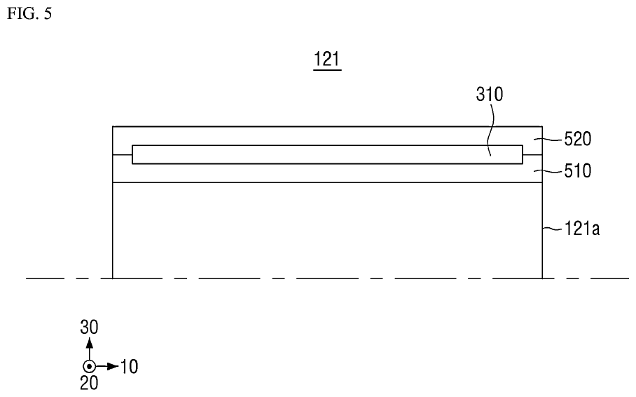

The first air layer 310 may be formed using two thin metal plates. Referring to FIG. 5, a first metal plate 510 may be bonded onto the body 121a, and a second metal plate 520 may be bonded onto the first metal plate 510. Here, a space enclosed by the first metal plate 510 and the second metal plate 520 may be formed between the first metal plate 510 and the second metal plate 520. The space thus formed may be the first air layer 310. FIG. 5 is an exemplary view for explaining a method of forming the first air layer 310 constituting the heating plate 121 of FIG. 3.

The first metal plate 510 and the second metal plate 520 may be made of a metal having excellent heat resistance or fire resistance in consideration of the fact that they are used as components of the heating plate 121.

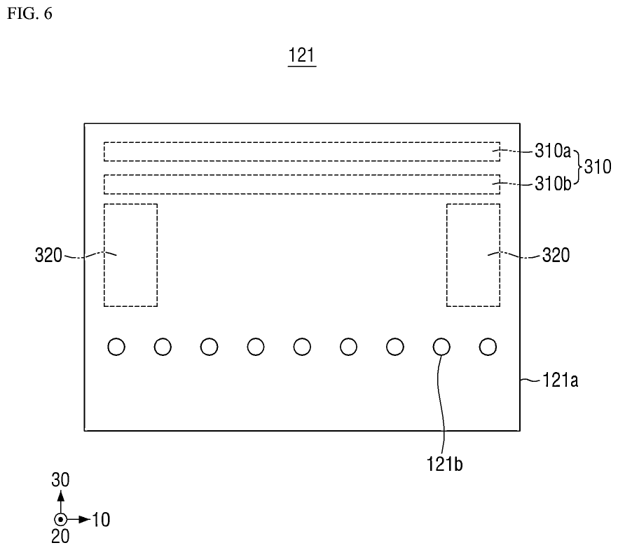

The first air layer 310 may be formed such that the flow of air is blocked from the outside, unlike the spaces 410, 420, 430 and 440 for air purge and exhaust flow. The first air layer 310 may be formed in a single layer in a height direction (the third direction 30) of the body 121a. However, the current embodiment is not limited thereto. The first air layer 310 may also be formed in a plurality of layers in the height direction 30 of the body 121a. For example, the first air layer 310 may include a first layer 310a and a second layer 310b at different levels as illustrated in FIG. 6. Here, the levels may be based on a direction perpendicular to the height direction 30 of the body 121a (i.e., a direction parallel to a width direction (the first direction 10) of the body 121a). FIG. 6 is an exemplary view for explaining various embodiments of the first air layer 310 constituting the heating plate 121 of FIG. 3.

When the first air layer 310 is formed in a plurality of layers in the height direction 30 of the body 121a, it may be formed using a plurality of thin metal plates as in the case where it is formed in a single layer in the height direction 30 of the body 121a. For example, when the first air layer 310 includes the first layer 310a and the second layer 310b as described with reference to FIG. 6, the first metal plate 510 may be bonded onto the body 121a, the second metal plate 520 may be bonded onto the first metal plate 510, and a third metal plate may be bonded onto the second metal plate 520. Here, the first layer 310a enclosed by the first metal plate 510 and the second metal plate 520 may be formed between the first metal plate 510 and the second metal plate 520, and the second layer 310b enclosed by the second metal plate 520 and the third metal plate may be formed between the second metal plate 520 and the third metal plate.

When the first air layer 310 is formed in a plurality of layers in the height direction 30 of the body 121a, the layers may be formed to have the same size. However, the current embodiment is not limited thereto. The layers may also be formed to have different sizes. Alternatively, some of the layers may be formed to have the same size, and some other layers may be formed to have different sizes.

Alternatively, the first air layer 310 may include a plurality of layers at different levels, and the levels may be based on a direction parallel to the height direction 30 of the body 121a.

Like the first air layer 310, the second air layer 320 may be formed by filling an empty space with air. The second air layer 320 may be formed in a side portion inside the body 121a. Specifically, the second air layer 320 may be formed adjacent to an outer surface of the body 121a in the body 121a. When the heating plate 121 further includes the second air layer 320 therein in addition to the first air layer 310, the temperature uniformity of a substrate can be further improved during a bake process of the substrate due to the thermal insulation effect of the first air layer 310 and the second air layer 320.

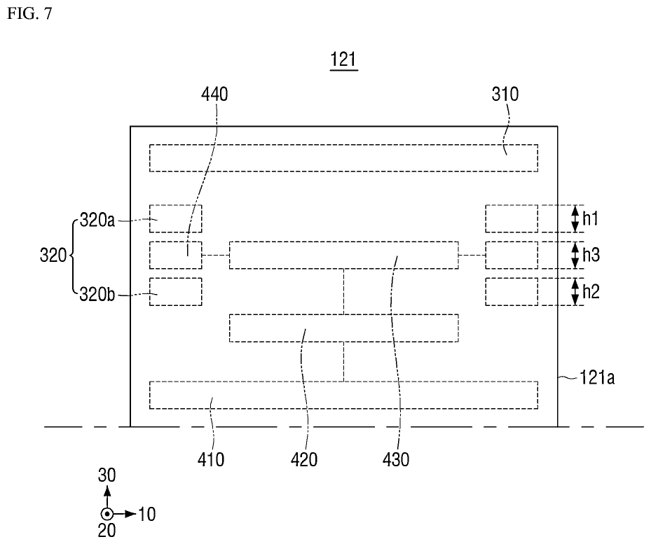

As described above, the body 121a may include four spaces 410, 420, 430 and 440 for air purge and exhaust flow. As illustrated in FIG. 7, the second air layer 320 may be formed on the same line as the fourth space 440 which is one of the four spaces 410, 420, 430 and 440. FIG. 7 is a first exemplary view illustrating the placement structure of the second air layer 320 constituting the heating plate 121 of FIG. 3.

Like the first air layer 310, the second air layer 320 may be formed such that the flow of air is blocked from the outside. The second air layer 320 may be separated from the fourth space 440.

The first through fourth spaces 410 through 440 are spaces formed to allow the flow of air. Here, the fourth space 440 may be directly or indirectly connected to the first space 410, the second space 420, the third space 430 and the outside so that air can be discharged to the outside and may be disposed on sides of the third space 430. On the other hand, the second air layer 320 may be completely separated from the fourth space 440. Accordingly, the flow of air may be blocked from the outside.

The second air layer 320 may be formed above and below the fourth space 440. Here, the second air layer 320 formed above the fourth space 440 is defined as a third layer 320a, and the second air layer 320 formed below the fourth space 440 is defined as a fourth layer 320b. However, the current embodiment is not limited thereto. The second air layer 320 may also be configured to include only one of the third layer 320a and the fourth layer 320b.

When the third layer 320a and the fourth layer 320b are separated from the fourth space 440, the size of the fourth space 440 may be maintained as it is. In other words, the sum of a height h1 of the third layer 320a, a height h2 of the fourth layer 320b, and a height h3 of the fourth space 440 after separation may be equal to a height h4 (h1+h2+h3=h4) of the fourth space 440 before separation.

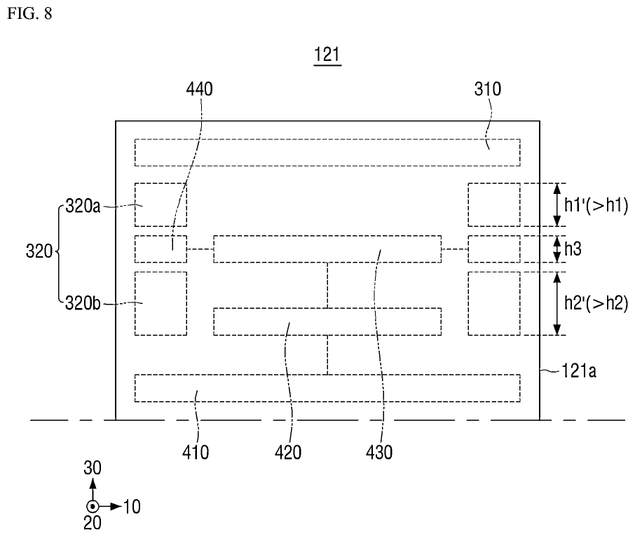

In order to increase thermal insulation performance, the third layer 320a and the fourth layer 320b may be extended in the height direction of the body 121a to have a larger area than in the above case. Referring to the example of FIG. 8, the third layer 320a may be extended in an upward direction of the body 121a (h1′>h1). In this case, the third layer 320a may be extended to a level close to the first air layer 310 or may be extended to a level in contact with the first air layer 310. The fourth layer 320b may be extended in a downward direction of the body 121a (h2′>h2). In this case, the fourth layer 320b may be extended to a level close to the first space 410 or may be extended to a level equal to that of the second space 420. FIG. 8 is a second exemplary view illustrating the placement structure of the second air layer 320 constituting the heating plate 121 of FIG. 3.

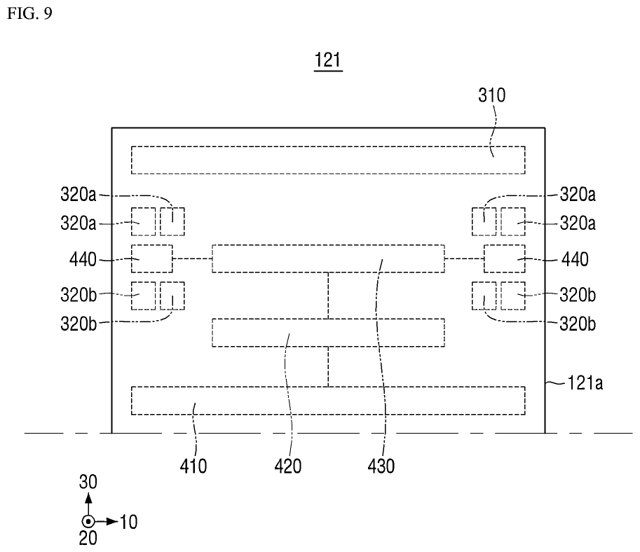

Each of the third layer 320a and the fourth layer 320b may be formed in a single layer in the width direction (the first direction 10) of the body 121a. However, in order to increase the thermal insulation performance, each of the third layer 320a and the fourth layer 320b may also be formed in a plurality of layers in the width direction (the first direction 10) of the body 121a. For example, each of the third layer 320a and the fourth layer 320b may include two layers at different levels as shown in the example of FIG. 9. Here, the levels may be based on the direction parallel to the height direction 30 of the body 121a. FIG. 9 is a third exemplary view illustrating the placement structure of the second air layer 320 constituting the heating plate 121 of FIG. 3.

Alternatively, each of the third layer 320a and the fourth layer 320b may include a plurality of layers at different levels, and the levels may be based on the direction perpendicular to the height direction 30 of the body 121a (i.e., the direction parallel to the width direction 10 of the body 121a).

When each of the third layer 320a and the fourth layer 320b includes a plurality of layers in the width direction 10 of the body 121a, the number of layers of the third layer 320a may be equal to the number of layers of the fourth layer 320b. However, the current embodiment is not limited thereto. The number of layers of the third layer 320a may also be different from the number of layers of the fourth layer 320b. For example, in order to increase the thermal insulation performance for an upper surface of the heating plate 121 on which a substrate is mounted, the number of layers of the third layer 320a may be greater than the number of layers of the fourth layer 320b.

When the third layer 320a includes a plurality of layers in the width direction 10 of the body 121a, the layers may be formed to have the same size. However, the current embodiment is not limited thereto. The layers may also be formed to have different sizes. Alternatively, some of the layers may be formed to have the same size, and some other layers may be formed to have different sizes.

Similarly, when the fourth layer 320b includes a plurality of layers in the width direction 10 of the body 121a, the layers may be formed to have the same size. However, the current embodiment is not limited thereto. The layers may also be formed to have different sizes. Alternatively, some of the layers may be formed to have the same size, and some other layers may be formed to have different sizes.

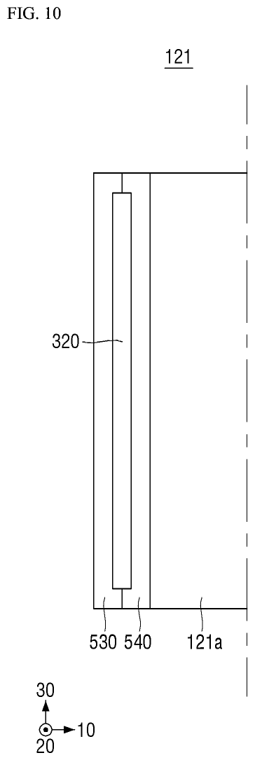

The second air layer 320 may be separated from the fourth space 440 as described above. However, like the first air layer 310, the second air layer 320 may also be formed using two thin metal plates. For example, referring to FIG. 10, a fourth metal plate 530 may be bonded onto the outer surface of the body 121a, and a fifth metal plate 540 may be bonded onto the fourth metal plate 530. Here, a space enclosed by the fourth metal plate 530 and the fifth metal plate 540 may be formed between the fourth metal plate 530 and the fifth metal plate 540. The space thus formed may be the second air layer 320. FIG. 10 is an exemplary view for explaining a method of forming the second air layer 320 constituting the heating plate 121 of FIG. 3.

The heating plate 121 may also include only one of the first air layer 310 and the second air layer 320.

The internal structure of the heating plate 121 has been described above with reference to FIGS. 3 through 10. The present disclosure relates to the formation of an air layer for thermal insulation of a bake chamber, and more particularly, to a structure in which an air layer capable of thermally insulating the surface of a chamber is formed to improve the temperature uniformity of a substrate in a bake process.

A conventional bake chamber is not structured for the purpose of thermal insulation. Accordingly, the amount of heat lost to the outside increases, thus degrading internal temperature uniformity performance. Heat transfer can be reduced by increasing the thickness of the chamber. However, this brings about far less effect than thermal insulation and increases the time required to raise temperature due to an increase in heat capacity.

According to the present disclosure, an air layer may be formed on upper and side surfaces of a conventional bake chamber without changing the internal space of the bake chamber (that is, maintaining the internal space of the conventional chamber as it is).

Specifically, an air insulating layer on the upper surface may be formed between two thin metal plates and may be sealed as much as possible so that it is not affected by the flow of air, thus improving thermal insulation performance. In addition, an air insulating layer on the side surfaces may be an additional insulating layer formed to have no air movement by separating a space while maintaining the existing structure. Accordingly, in the present disclosure, the use of a metal material that forms the chamber is reduced as compared with the existing structure, thus reducing the heat capacity and increasing the temperature increase rate.

The features of the present disclosure described above are summarized as follows.

First, an insulation structure having an air layer in which fluid flow is minimized is formed in a bake chamber.

Second, an upper air layer is formed using two thin metal plates.

Third, a side air layer is formed by separating a space using an existing internal structure.

Fourth, the weight of the entire chamber is minimized to reduce the heat capacity.

In addition, the effects of the present disclosure described above are summarized as follows.

First, since the body of the chamber is changed to a dual structure in which an air layer is formed, the thermal insulation effect of the chamber body using the air layer can be improved.

Second, feasibility test results showed that the temperature distribution uniformity was improved by about 30%.

Third, the heat capacity can be reduced by reducing the weight of the chamber compared with the existing structure, and the temperature increase rate can also be reduced.

While the present disclosure has been particularly illustrated and described with reference to exemplary embodiments thereof, it will be understood by those of ordinary skill in the art that various changes in form and detail may be made therein without departing from the scope of the present disclosure as defined by the following claims. The exemplary embodiments should be considered in a descriptive sense only and not for purposes of limitation.

What is claimed is:

1. A substrate treating apparatus comprising:
a housing providing a space in which a substrate is treated;
a heating unit disposed in the housing and heating the substrate;
a cooling unit disposed in the housing and cooling the substrate; and
a transfer unit for moving the substrate,
wherein the heating unit comprises:
a body comprising a heater therein;
a first air layer provided inside the body for thermal insulation and formed in a first direction as a longitudinal direction thereof; and
a second air layer provided inside the body for thermal insulation and formed in a second direction as a longitudinal direction thereof.

2. The apparatus of claim 1, wherein the second direction is perpendicular to the first direction.

3. The apparatus of claim 1, wherein the first air layer is provided adjacent to an upper surface of the body.

4. The apparatus of claim 1, wherein the second air layer is provided adjacent to an outer surface of the body.

5. The apparatus of claim 1, wherein a space for air purge and exhaust is formed inside the body, and the first air layer is provided in an upper portion of the space.

6. The apparatus of claim 1, wherein the first air layer is sealed between two different metal plates sequentially bonded onto the body.

7. The apparatus of claim 1, wherein the first air layer is comprised of a plurality of layers at different levels.

8. The apparatus of claim 7, wherein the levels are based on a direction parallel to a width direction of the body.

9. The apparatus of claim 1, wherein a space for air purge and exhaust is formed inside the body and comprises a first space, a second space connected to the first space and disposed above the first space, a third space connected to the second space and disposed above the second space and a fourth space connected to the third space and disposed on sides of the third space, and the second air layer is provided at the same level as the fourth space.

10. The apparatus of claim 9, wherein the levels are based on a direction parallel to a height direction of the body.

11. The apparatus of claim 9, wherein the second air layer is separated from the fourth space.

12. The apparatus of claim 11, wherein the second air layer is not connected to the first through fourth spaces.

13. The apparatus of claim 9, wherein the second air layer comprises:
a third layer disposed above the fourth space; and
a fourth layer disposed below the fourth space.

14. The apparatus of claim 9, wherein the second air layer is comprised of a plurality of layers at different levels, and the levels are based on a direction parallel to a height direction of the body.

15. A substrate treating apparatus comprising:
a housing providing a space in which a substrate is treated;
a heating unit disposed in the housing and heating the substrate;
a cooling unit disposed in the housing and cooling the substrate; and
a transfer unit for moving the substrate,
wherein the heating unit comprises:
a body comprising a heater therein and having a space for air purge and exhaust;
a first air layer provided inside the body for thermal insulation and formed in a first direction as a longitudinal direction thereof; and
a second air layer provided inside the body for thermal insulation and formed in a second direction as a longitudinal direction thereof,
wherein the space for air purge and exhaust comprises a first space, a second space connected to the first space and disposed above the first space, a third space connected to the second space and disposed above the second space and a fourth space connected to the third space and disposed on sides of the third space, the first air layer is provided above the third space and the fourth space, and the second air layer is provided at the same level as the fourth space but is separated from the fourth space.

16. A heating unit for heat-treating a substrate and comprising:
a heating plate comprising a body providing a surface on which the substrate is mounted and a heater installed inside the body;
a cover covering a top of the heating plate when the substrate is heat-treated; and
an actuator for moving the cover,
wherein the heating plate comprises:
a first air layer provided inside the body for thermal insulation and formed in a first direction as a longitudinal direction thereof; and
a second air layer provided inside the body for thermal insulation and formed in a second direction as a longitudinal direction thereof.

17. The heating unit of claim 16, wherein the second direction is perpendicular to the first direction.

18. The heating unit of claim 16, wherein a space for air purge and exhaust is formed inside the body, and the first air layer is provided in an upper portion of the space.

19. The heating unit of claim 16, wherein a space for air purge and exhaust is formed inside the body and comprises a first space, a second space connected to the first space and disposed above the first space, a third space connected to the second space and disposed above the second space and a fourth space connected to the third space and disposed on sides of the third space, and the second air layer is provided at the same level as the fourth space.

20. The heating unit of claim 16, being applied when a photolithography process is performed on the substrate.
